(19) United States
(12) Patent Application Publication
(10) Pub. No.: US 2014/0140025 A1
(43) Pub. Date: May 22, 2014

(54) SERVER BACKPLANE

(71) Applicants: Hon Hai Precision Industry Co., Ltd., New Taipei (TW); Hong Fu Jin Precision Industry (ShenZhen) Co., Ltd, Shenzhen (CN)

(72) Inventors: YU HAN, Shenzhen (CN); JUN-HUI WANG, Shenzhen (CN); ZHENG-HENG SUN, New Taipei (TW)

(73) Assignees: Hon Hai Precision Industry Co., Ltd., New Taipei (TW); Hong Fu Jin Precision Industry (ShenZhen) Co., Ltd, Shenzhen (CN)

(21) Appl. No.: 14/084,625

(22) Filed: Nov. 20, 2013

(30) Foreign Application Priority Data
Nov. 21, 2012 (CN) 2012104746089

(51) Int. Cl. H05K 7/14

(52) U.S. Cl. CPC H05K 7/1438
USPC 361/760; 439/527

(57) ABSTRACT

A backplane includes a main body with a top side, a bottom side, and two ends connected between the top and bottom sides. A first connector is arranged on a first surface of the main body, and a number of second connectors are arranged on a second surface of the main body opposite to the first surface. A first edge connector is attached on one of the ends the main body, and a first socket is attached on the other end of the main body. The second connectors are coupled to a number of hard disk drives. The first socket is electrically coupled to the first edge connector and the second connectors.

### BACKGROUND

1. Technical Field

The present disclosure relates to a server backplane.

2. Description of Related Art

Hard disk drive (HDD) backplanes become an essential part of a server. The HDD backplane can be used to connect a plurality of HDDs. However, different types of servers, such as 1 unit (U) and 2U, may require different types of backplanes, which cost time to design a new backplane when the type of the servers changes.

Therefore, there is room for improvement in the art.

### BRIEF DESCRIPTION OF THE DRAWINGS

Many aspects of the present disclosure can be better understood with reference to the following drawing(s). The components in the drawing(s) are not necessarily drawn to scale, the emphasis instead being placed upon clearly illustrating the principles of the present disclosure. Moreover, in the drawing(s), like reference numerals designate corresponding parts throughout the several views.

FIG. 1 is an isometric view of an embodiment of a server backplane of the present disclosure, wherein the server backplane includes a socket.

FIG. 2 is similar to FIG. 1, but viewed from another perspective.

FIG. 3 is an enlarged view of the socket of FIG. 1, but viewed from another perspective.

FIG. 4 is an isometric view of two server backplanes of FIG. 1 arranged in a 1 unit (U) server.

FIG. 5 is an isometric view of four server backplanes of FIG. 1 arranged in a 2U server.

### DETAILED DESCRIPTION

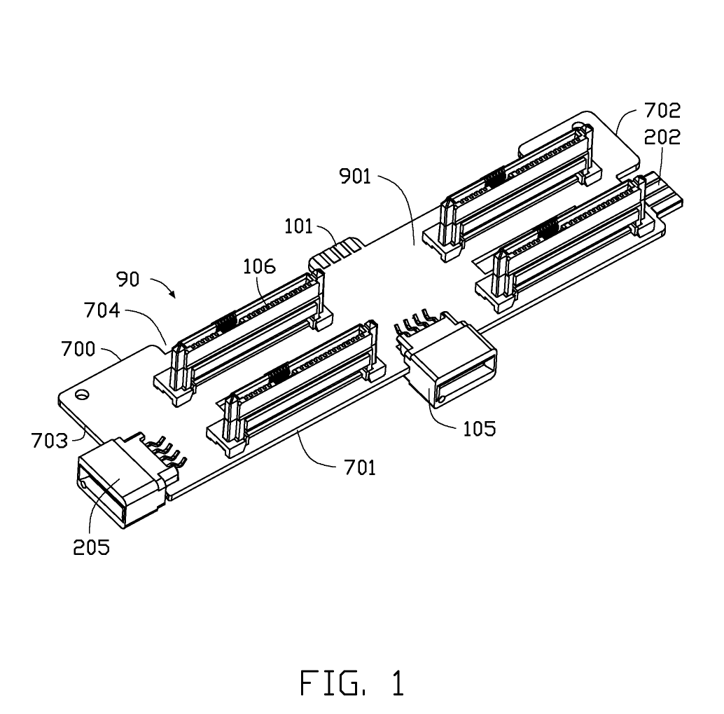

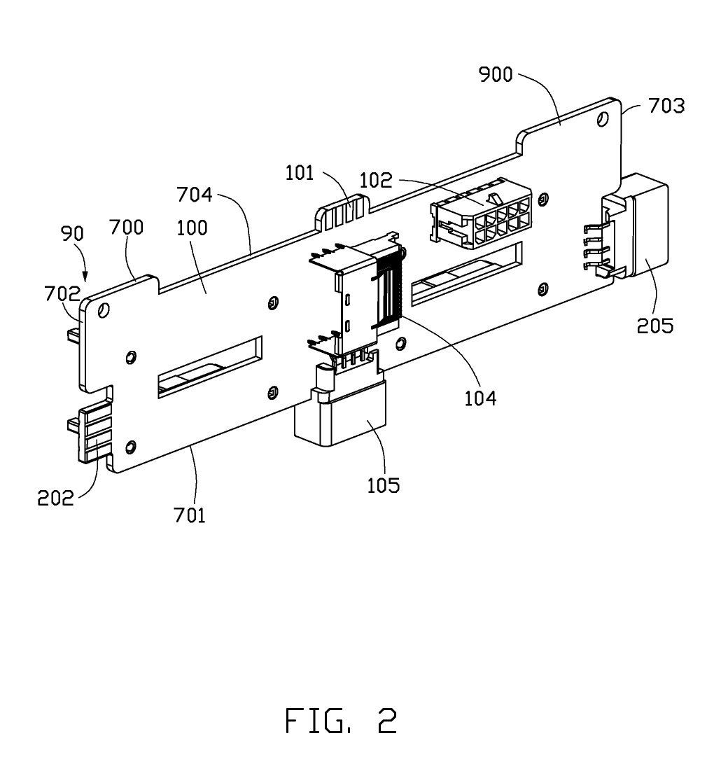

FIGS. 1 and 2 illustrate an embodiment of a server backplane 90 of the present disclosure. The server backplane 90 includes a substantially rectangular main body 100. A first surface 900 of the main body 100 is attached with a first connector 104, and a second surface 901 of the main body 100 opposite to the first surface 900 is attached with four second connectors 106 electrically coupled to the first connector 104. In the illustrated embodiment, the first connector 104 is a mini serial attached small computer system interface (SAS) connector, the second connectors 106 are SAS connectors.

The main body 100 includes a top side 700, a bottom side 701, and two opposite ends 702 and 703 connected between the top side 700 and the bottom side 701. The top side 700 defines a recess 704 in the middle of the top side 700. A first edge connector 101 extends from the middle of a bottom wall bounding the recess 704, and the height of the first edge connector 101 is less than the depth of the recess 704. A height of the main body 100 between the top side 700 and the bottom side 701 is not greater than a height of a 1 unit (U) of a server.

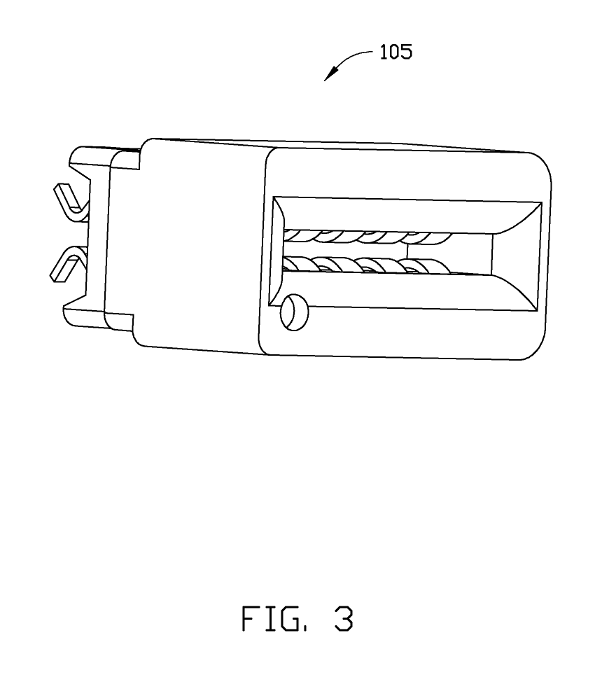

FIG. 3 shows that a first socket 105 mounted to the bottom side 701 is electrically coupled to the first edge connector 101. A beeline between the first edge connector 101 and the first socket 105 is parallel to the ends 702 and 703. The first socket 105 is electrically connected to the second connectors 106.

The ends 702 and 703 of the main body 100 form a second edge connector 202 and a second socket 205, respectively. The second edge connector 202 is the same as the first edge connector 101, and the second socket 205 is the same as the first socket 105. The second edge connector 202 is electrically coupled to the second socket 205. A beeline between the second socket 205 and the second edge connector 202 is parallel to the top and bottom sides 700 and 701. The second socket 205 is electrically connected to the second connectors 106.

The first surface 900 of the main body 100 also forms a power connector 102 electrically coupled to the first and second edge connectors 101 and 202, the first and second sockets 105 and 205, and the first and second connectors 104 and 106. When the power connector 102 acquires power from external power source, the power connector 102 provides power for the first and second edge connectors 101 and 202, the first and second sockets 105 and 205, and the first and second connectors 104 and 106. In other embodiments, each of the power connector 102, the first and second sockets 105 and 205, and the first and second edge connectors 101 and 202 can be attached to any suitable place of the main body 100.

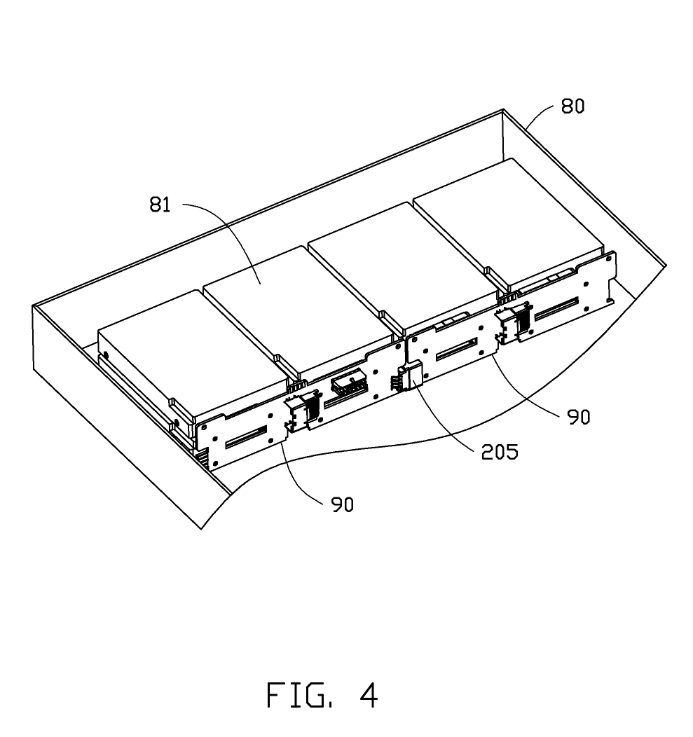

FIG. 4 shows two server backplanes 90 with eight hard disk drives (HDD) 81 mounted to the second connectors 106 are juxtapositionally arranged in a 1U server 80. The second edge connector 202 mounted to the end 702 of one of the server backplanes 90 is plugged into the second socket 205 mounted to the end 703 of the other server backplane 90. When the power connector 102 of one of the server backplanes 90 is connected to the external power source, the power connector 102 provides power for the four HDDs 81 arranged on the second surface 901 of the server backplane 90, and also provides power for the four HDDs 81 of the other server backplane 90 through the second edge connector 202 of the one of the server backplanes 90 and the second socket 205 of the other server backplane 90, in that order.

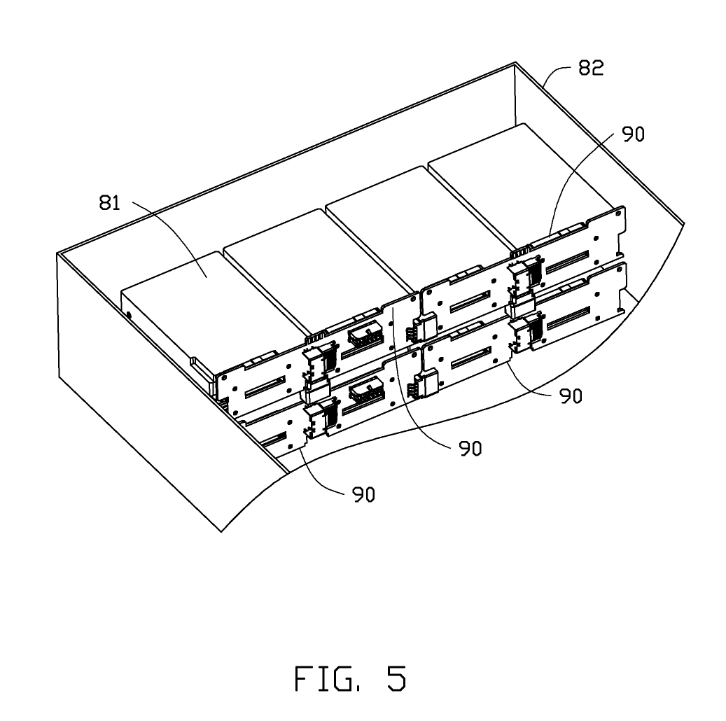

FIG. 5 shows that four server backplanes 90 each mounted with four HDDs 81 are arranged in a 2U server 82. Two lower server backplanes 90 are juxtapositionally arranged, and two upper server backplanes are juxtapositionally arranged above the lower server backplanes 90. The second edge connector 202 of one of the lower server backplanes 90 is plugged into the second socket 205 of the other lower server backplane 90. The second edge connector 202 of one of the upper server backplanes 90 is plugged into the second socket 205 of the other upper server backplane 90. The first edge connector 101 of each lower server backplane 90 is plugged into the first socket 105 of a corresponding one of the upper server backplane 90. The external power source can be connected to the power connector 102 of one of the server backplanes 90, and all the HDDs 81 can acquire power.

While the disclosure has been described by way of example and in terms of a preferred embodiment, it is to be understood that the disclosure is not limited thereto. On the contrary, it is intended to cover various modifications and similar arrangements as would be apparent to those skilled in the art. Therefore, the range of the appended claims should be accorded the broadest interpretation so as to encompass all such modifications and similar arrangements.

What is claimed is:

1. A backplane, comprising:
a main body with two opposite sides, and two opposite ends connected between the sides;
a first connector arranged on a first surface of the main body;
a plurality of second connectors arranged on a second surface of the main body opposite to the first surface, to be coupled to a plurality of hard disk drives;
a first edge connector attached on one of the sides or one of the ends of the main body;
a first socket attached on an opposite one of the sides or an opposite one of the ends of the main body, and electrically coupled to the first edge connector and the plurality of second connectors.

2. The backplane of claim 1, further comprising:
a power connector arranged on the first surface of the main body, wherein the power connector is electrically coupled to the first edge connector, the first socket, and the plurality of second connectors.

3. The backplane of claim 2, wherein the main body is substantially rectangular, wherein the first edge connector is attached on one of the sides of the main body, and the first socket is attached on the opposite side of the main body.

4. The backplane of claim 3, wherein a beeline between the first edge connector and the first socket is parallel to the ends.

5. The backplane of claim 3, further comprising:
a second edge connector formed on one of the ends of the main body, and a second socket formed on the opposite end of the main body, wherein the second socket is electrically coupled to the second edge connector and the plurality of second connectors.

6. The backplane of claim 4, wherein a beeline between the second edge connector and the second socket is parallel to the sides.

7. The backplane of claim 2, wherein the main body is substantially rectangular, the first edge connector is attached on one of the ends of the main body, and the first socket is attached on the opposite end of the main body.

8. The backplane of claim 7, wherein a beeline between he first edge connector and the first socket is parallel to the sides.

9. A server backplane assembly, comprising:
two backplanes each comprising:
a main body with two opposite sides, and two opposite ends connected between the sides;
a first connector arranged on a first surface of the main body; and
a plurality of second connectors arranged on a second surface of the main body opposite to the first surface, to be coupled to a plurality of hard disk drives;
an edge connector attached on one of the sides or one of the ends of the main body; and
a socket attached on an opposite one of the sides or an opposite one of the ends of the main body, and electrically coupled to the edge connector and the plurality of second connectors;
wherein the backplanes are juxtapositionally arranged, the edge connector of one of the backplanes is plugged into the socket of the other backplane.

10. The server backplane assembly of claim 9, wherein each backplane further comprises:
a power connector arranged on the first surface of the main body;
wherein the power connector is electrically coupled to the edge connector, the socket, and the plurality of second connectors.

11. The server backplane assembly of claim 9, wherein the edge connector of each backplane is attached on one of the sides of the main body, and the socket of each backplane is attached on an opposite side of the main body.

12. The server backplane assembly of claim 9, wherein the edge connector of each backplane is attached on one of the ends of the main body, and the socket of each backplane is attached on an opposite end of the main body.

13. The server backplane assembly of claim 9, wherein a height of each backplane in a direction parallel to the ends equals to a 1 unit of a server.
